(19) United States
(12) Patent Application Publication
(10) Pub. No.: US 2026/0191027 A1
(43) Pub. Date: Jul. 2, 2026

(54) MANUFACTURING METHOD FOR PACKAGING SUBSTRATE

(71) Applicant: Absolics Inc., Covington, GA (US)

(72) Inventor: Younggyu LEE, Covington, GA (US)

(73) Assignee: Absolics Inc., Covington, GA (US)

(21) Appl. No.: 19/435,605

(22) Filed: Dec. 29, 2025

Related U.S. Application Data
(60) Provisional application No. 63/740,330, filed on Dec. 31, 2024.

(51) Int. Cl. H10W 70/05

(52) U.S. Cl. CPC H10W 70/05

(57) ABSTRACT

A method of manufacturing a packaging substrate according to the present disclosure comprises a resist pattern layer forming step of forming a resist pattern layer on a base substrate comprising a core layer and a metal base layer formed on the core layer. The resist pattern layer forming step comprises a lamination process of laminating a resist layer on the base substrate and an exposure process of selectively exposing the resist layer. The resist pattern layer comprises pattern holes having a diameter of 20 μm or less. The resist layer comprises a negative resist. An exposure dose of the exposure process is from 170 mJ/cm² to 215 mJ/cm².

In this case, hole patterns having a fine pitch may be more accurately and densely formed in an insulating layer.

### TECHNICAL FIELD

The present disclosure relates to a method of manufacturing a packaging substrate.

### BACKGROUND ART

In manufacturing an electronic component, implementing a circuit on a semiconductor wafer is referred to as a front-end process (FE: Front-End), and assembling a wafer into a state capable of being used in an actual product is referred to as a back-end process (BE: Back-End), and a packaging process is included in the back-end process.

Recently, four core technologies of the semiconductor industry that have enabled rapid development of electronic products include semiconductor technology, semiconductor packaging technology, manufacturing process technology, and software technology. Semiconductor technology has been developed in various forms such as line widths of micro-or-less nano units, ten million or more cells, high-speed operation, and a large amount of heat dissipation, but relatively, technology for perfectly packaging the same has not been sufficiently supported. Accordingly, electrical performance of a semiconductor is sometimes determined by packaging technology and electrical connection according thereto, rather than performance of the semiconductor technology itself.

Recently, studies applying a ceramic material to a high-end packaging substrate are in progress. By forming a through hole in a ceramic material substrate and applying a conductive material to the through hole, a wiring length between a device and a motherboard may be shortened and excellent electrical characteristics may be obtained.

### PRIOR ART DOCUMENTS

### Patent Documents

Korean patent publication No. 10-2022-0135842
Korean patent publication No. 10-2014-0085023

### CONTENT OF THE INVENTION

### Problem to be Solved

An object of the present disclosure is to provide a method of manufacturing a packaging substrate capable of forming, more accurately and densely, a hole pattern having a fine pitch in an insulating layer.

### Means for Solving the Problem

A method of manufacturing a packaging substrate according to one embodiment of the present disclosure includes a resist pattern layer forming step of forming a resist pattern layer on a base substrate including a core layer and a metal base layer formed on the core layer.

The resist pattern layer forming step includes a lamination process of laminating a resist layer on the base substrate and an exposure process of selectively exposing the resist layer.

The resist pattern layer includes pattern holes having a diameter of 20 μm or less.

The resist layer includes a negative resist.

An exposure dose of the exposure process is from 170 mJ/cm² to 215 mJ/cm².

The resist pattern layer forming step may further include a development process of developing the exposed resist layer to form the resist pattern layer.

In the development process, a developer may be sprayed onto the resist layer to form the resist pattern layer.

In the development process, a spray pressure of the developer may be from 0.13 MPa to 3 MPa.

A temperature of the developer may be 20° C. or higher and lower than 30° C.

In the lamination process, the resist layer may be laminated in contact with the metal base layer using a roll laminator.

A roll pressure of the roll laminator may be from 0.3 MPa to 1 MPa.

A roll temperature of the roll laminator may be from 105° C. to 130° C.

A laminating speed of the roll laminator may be from 1 m/min to 2 m/min.

The method of manufacturing a packaging substrate may further include a metal mask layer forming step of selectively wet-etching the metal base layer using the resist pattern layer to provide a metal mask layer.

The base substrate may further include an insulating layer disposed between the metal mask layer and the core layer.

The method of manufacturing a packaging substrate may further include an insulating pattern layer forming step of selectively plasma-etching the insulating layer using the metal mask layer to form an insulating pattern layer.

In the insulating pattern layer forming step, the insulating layer may be selectively plasma-etched in an atmosphere including a first etching gas and a second etching gas.

The first etching gas may be a fluorine-based gas.

The second etching gas may be oxygen gas.

### Advantageous Effects

The method of manufacturing a packaging substrate of the present disclosure may form, more accurately and densely, a hole pattern having a fine pitch in an insulating layer.

### BRIEF DESCRIPTION OF THE DRAWINGS

FIG. 1 is a cross-sectional view illustrating a base substrate of the present disclosure.

FIG. 2 is a cross-sectional view illustrating a resist pattern layer of the present disclosure.

FIG. 3 is a cross-sectional view illustrating a metal mask layer of the present disclosure.

FIG. 4 is a cross-sectional view illustrating an insulating pattern layer of the present disclosure.

FIG. 5 is a cross-sectional view illustrating a packaging substrate manufactured according to a manufacturing method of the present disclosure.

### DETAILED DESCRIPTION OF THE INVENTION

Hereinafter, embodiments will be described in detail with reference to the accompanying drawings so that a person having ordinary skill in the art to which the present invention pertains may easily practice the same. However, the present invention may be embodied in various different forms and is not limited to the embodiments described herein. Similar parts are designated by similar reference numerals throughout the specification.

Throughout the specification, the term “combination thereof” included in a Markush-type expression means one or more mixtures or combinations selected from a group consisting of components described in the Markush-type expression, and means including one or more selected from the group consisting of the components.

Throughout the specification, terms such as “first,” “second,” or “A,” “B” are used to distinguish the same terms from each other. In addition, singular expressions include plural expressions unless the context clearly indicates otherwise.

In the present specification, the term “-based” refers to a compound comprising “-” itself or a derivative thereof.

In the present specification, the meaning that B is positioned on A means that B is positioned in direct contact on A or that B is positioned on A with another layer positioned therebetween, and is not construed as being limited to B being positioned in contact with a surface of A.

In the present specification, the meaning that B is connected on A means that A and B are directly connected or that A and B are connected through another component between A and B, and, unless otherwise stated, is not construed as being limited to A and B being directly connected.

In the present specification, singular expressions, unless otherwise described, are construed as meanings including singular or plural as interpreted in context.

In the present specification, shapes, relative sizes, angles, and the like of respective components in the drawings are illustrative and may be exaggerated for the purpose of description, and rights are not construed as being limited to the drawings.

In the present specification, A and B being adjacent means that A and B are positioned in contact or that A and B are not in contact but are positioned close to each other. In the present specification, the expression that A and B are adjacent, unless otherwise stated, is not construed as being limited to A and B being positioned in contact.

In the present specification, “fine line,” unless otherwise described, means a line having a width of 5 μm or less, and, for example, means a line having a width of 1 μm to 4 μm or less.

Hereinafter, the present disclosure will be described.

The method of manufacturing a packaging substrate of the present disclosure includes a resist pattern layer forming step of forming a resist pattern layer on a base substrate including a core layer and a metal base layer formed on the core layer.

### Resist Pattern Layer Forming Step

### Base Substrate

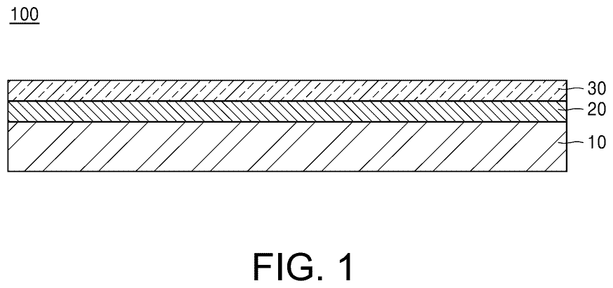

FIG. 1 is a cross-sectional view illustrating a base substrate of the present disclosure. The method of manufacturing a packaging substrate of the present disclosure will be described with reference to FIG. 1.

In the resist pattern layer forming step, a base substrate (100) including a core layer (10) and a metal base layer (30) formed on the core layer (10) may be provided. The base substrate (100) may further include an insulating layer (20) disposed between the core layer (10) and the metal base layer (30).

The core layer (10) may have a shape of a substrate. The core layer (10) is not particularly limited as long as it is a substrate applicable as an electronic component.

As a material of the core layer (10), an organic material, glass, alumina, aluminum nitride, silicon carbide, silicon nitride, or the like may be applied.

The core layer (10) may be a glass core. The core layer (10) may be, for example, alkali borosilicate sheet glass, alkali-free borosilicate sheet glass, or alkali-free alkali-earth borosilicate sheet glass. The core layer (10) may be a glass substrate for an electronic device, and, for example, one manufactured by SCHOTT, AGC, Corning, or the like may be applied, but is not limited thereto.

The core layer (10) may include an upper surface and a side surface connected to the upper surface and formed in a thickness direction of the core layer (10). A surface of the core layer (10) may include a lower surface facing the upper surface.

That the side surface is formed in the thickness direction of the core layer (10) means not only that the side surface forms a right angle with the upper surface of the core layer (10), but also includes that at least a portion of the side surface forms an angle other than 90 degrees (an inclined angle) with respect to the upper surface.

The side surface may be a planar surface or a curved surface.

The core layer (10) may include a cavity (not shown), which is a space formed by a portion of the core layer (10) being recessed inward.

The cavity may be formed by a portion of the upper surface and/or lower surface side of the core layer (10) being recessed in the thickness direction of the core layer (10), or may penetrate through the core layer (10) in the thickness direction.

The cavity may provide a space in which a device may be mounted. A device mounted in the cavity may be electrically connected to other components within the packaging substrate. The device may include not only semiconductor devices such as a CPU, a GPU, and a memory chip, but also a capacitor device, a transistor device, an impedance device, and other modules. That is, any device mounted in a semiconductor device may be applied as the device without limitation.

The core layer (10) may include a through-via portion (not shown) penetrating the core layer (10) in the thickness direction.

The through-via portion includes a via space, which is a space in which an electrical conductive layer is disposed, and a via inner diameter surface surrounding the via space. The via inner diameter surface means a surface of the core layer (10) formed inside the through-via portion.

The via space may have a substantially uniform inner diameter in the thickness direction of the core layer (10). Alternatively, the via space may have an inner diameter that varies in the thickness direction of the core layer (10).

When a glass core is applied as the core layer (10), the through-via portion may be provided by etching the glass core. Specifically, defects may be formed at predetermined positions within a surface of the glass core. As a method of forming the defects, mechanical etching, laser irradiation, or the like may be applied.

The base substrate (100) may include an electrical conductive layer formed in the via space. The electrical conductive layer may be formed by filling at least a portion of the via space, or may be formed in a thin film form on the via inner diameter surface. When the electrical conductive layer is formed in a thin film form on the via inner diameter surface, a remaining space in the via space other than a space occupied by the electrical conductive layer may be filled with an insulating layer.

The electrical conductive layer disposed in the via space may transmit an electrical signal in the thickness direction of the core layer (10), and may electrically connect a device, a main board, a redistribution layer, and the like to each other.

Descriptions of materials of the insulating layer and the electrical conductive layer overlap with those described below and thus will be omitted.

The base substrate (100) may further include an insulating layer (20) disposed between the core layer (10) and the metal base layer (30). The insulating layer (20) may be formed in contact with an upper surface of the core layer (10). The base substrate (100) may further include an electrical conductive layer (not shown) disposed between the core layer (10) and the insulating layer (20). The insulating layer (20) may be disposed on the electrical conductive layer and surround the electrical conductive layer.

The insulating layer (20) is not particularly limited as long as it may be applied as an insulating layer (20) in a semiconductor device or a packaging substrate. For example, the insulating layer (20) may include an epoxy-based resin including a filler. The insulating layer (20) may be formed using, for example, a build-up layer material such as Ajinomoto Build-up Film (ABF) manufactured by Ajinomoto, an undercoat material, or the like, but is not limited thereto.

The electrical conductive layer corresponds to a conductor that transmits an electrical signal. The electrical conductive layer may include an electrically conductive material. For example, the electrical conductive layer may include at least one selected from a group consisting of copper, nickel, aluminum, gold, and silver. Copper or the like may be applied as a material of the electrical conductive layer.

In the resist pattern layer forming step, a base substrate (100) in which an insulating layer (20) is already formed between a core layer (10) and a metal base layer (30) may be provided. In the resist pattern layer forming step, the base substrate (100) may be provided by forming the insulating layer (20) on the core layer (10), and forming the metal base layer (30) on the insulating layer (20).

The insulating layer (20) may be formed by laminating a film-type insulating resin on the core layer (10). For example, the base substrate (100) may be formed by vacuum laminating the film-type insulating layer (20) on the core layer (10). In this case, a surface of a conductive layer disposed under the insulating layer (20) may be surrounded without voids.

The base substrate (100) may further comprise the metal base layer (30) formed on the core layer (10). The base substrate (100) may further comprise the metal base layer (30) formed on the insulating layer (20). The metal base layer (30) is a layer used to form a metal mask layer. The metal base layer (30) may comprise a metal element. The metal base layer (30) may be formed of a metal material. By applying a metal element as a material of the metal base layer (30), when patterning the insulating layer (20) through plasma etching, the metal mask layer may exhibit excellent plasma resistance characteristics and may contribute to accurately transferring a pattern to the insulating layer (20).

The metal base layer (30) may comprise at least one selected from the group consisting of copper, nickel, manganese, iron, tungsten, titanium, and combinations thereof. The metal base layer (30) may comprise copper. The metal base layer (30) may comprise copper in an amount of 95 at % or more. The metal base layer (30) may comprise copper in an amount of 99 at % or more. The metal base layer (30) may comprise copper in an amount of 100 at % or less.

A thickness of the metal base layer (30) may be from 100 nm to 1000 nm. The thickness may be 120 nm or more. The thickness may be 150 nm or more. The thickness may be 180 nm or more. The thickness may be 800 nm or less. The thickness may be 500 nm or less. In this case, a metal mask layer having etching resistance suitable for a plasma etching process may be provided.

The metal base layer (30) may be formed by deposition. The metal base layer (30) may be formed by a PVD (Physical Vapor Deposition) process. The metal base layer (30) may be formed by sputtering.

A method of forming the metal base layer is not limited as long as it is a method commonly used in the deposition field, and may be applied.

### Resist Pattern Layer

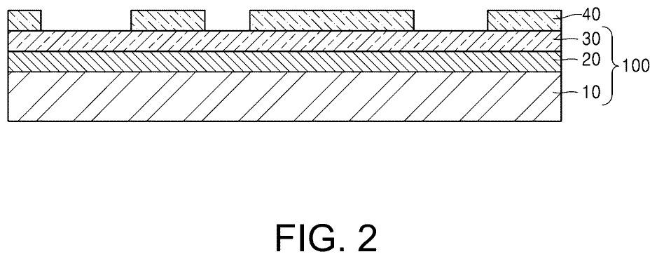

FIG. 2 is a cross-sectional view illustrating a resist pattern layer of the present disclosure. The present disclosure will be described with reference to FIG. 2.

What has been described above with reference to FIG. 1 may be equally applied to the base substrate (100) and the like. Hereinafter, differences will be mainly described.

In the resist pattern layer forming step, a resist pattern layer (40) may be formed on the base substrate (100). The resist pattern layer (40) may function as an etching mask when etching the metal base layer (30).

The resist pattern layer forming step comprises a lamination process of laminating a resist layer on the base substrate (100) and an exposure process of selectively exposing the resist layer.

### Lamination Process

In the lamination process, a resist layer may be laminated on the base substrate (100). In the lamination process, a resist layer may be laminated on the metal base layer (30). The resist layer may be formed in contact with an upper surface of the metal base layer (30). Another component may be disposed between the resist layer and the upper surface of the metal base layer (30).

In the lamination process, a resist layer may be formed by heating and pressurizing a dry film on the metal base layer (30) using a roll laminator.

The dry film may be a negative resist film. The resist layer may comprise a negative resist. When implementing a pattern having a fine pitch on the resist layer, the negative resist may be advantageous in suppressing deterioration in pattern accuracy due to diffraction.

The negative resist film is not particularly limited, as long as it is commonly used in the packaging substrate field. The negative resist film may comprise an acrylic-based resin. For example, the negative resist film may be the RY-5107 model manufactured by Showa Denko.

A thickness of the dry film may be from 3 μm to 30 μm. The thickness may be 5 μm or more. The thickness may be 20 μm or less. The thickness may be 15 μm or less. The thickness may be 9 μm or less. In this case, an aspect ratio of the resist pattern layer (40) may be adjusted, thereby contributing to precisely etching the metal base layer (30) while substantially suppressing collapse of the resist pattern layer (40).

In the lamination process, process conditions of the roll laminator may be controlled within a range preset in the present disclosure. Through this, the resist layer and the resist pattern layer (40) formed from the resist layer may be stably fixed and attached on the metal base layer (30), thereby helping to precisely transfer a pattern to the metal base layer (30).

The roll laminator is not limited as long as it is commonly used in the packaging substrate field. For example, an ATOCHEM Hot roller model may be applied as the roll laminator.

In the dry film lamination process, a roll pressure of the roll laminator may be from 0.3 MPa to 1 MPa. The roll pressure may be 0.4 MPa or more. The roll pressure may be 0.9 MPa or less. The roll pressure may be 0.8 MPa or less. The roll pressure may be 0.7 MPa or less. In this case, the dry film may be laminated while being brought into close contact with substantially no empty space over an entire upper surface of the metal base layer (30).

In the dry film lamination process, a roll temperature of the roll laminator may be from 105° C. to 130° C. The roll temperature may be 110° C. or higher. The roll temperature may be 125° C. or lower. In this case, the dry film may have excellent adhesion to the upper surface side of the metal base layer (30).

In the dry film lamination process, a laminating speed of the roll laminator may be 2 m/min or less. The laminating speed may be 1.9 m/min or less. The laminating speed may be 1.8 m/min or less. The laminating speed may be 1 m/min or more. In this case, the dry film may be heated and pressurized for a time sufficient to form stable bonding strength between the dry film and the upper surface side of the metal base layer (30). In addition, manufacturing time may be reduced to improve process efficiency.

### Exposure Process

In the exposure process, the resist pattern layer forming step may selectively expose the resist layer. In the exposure process, exposure light may be irradiated onto the resist layer according to a pre-designed pattern shape. The exposure light may be irradiated through a DLT (Digital Lithography Technology) apparatus, a laser direct imaging (LDI) exposure apparatus, or a selective exposure process using a photomask.

The exposure light may have a controlled wavelength band. Specifically, light having a wavelength of 405 nm may be applied as the exposure light.

According to the present disclosure, by applying a controlled exposure dose in the exposure process, hole patterns having pre-designed shapes and positions may be precisely formed in the resist layer.

The exposure dose of the exposure process may be from 170 mJ/cm² to 215 mJ/cm². The exposure dose may be 175 mJ/cm² or more. The exposure dose may be 210 mJ/cm² or less. The exposure dose may be 200 mJ/cm² or less. In this case, when forming fine patterns in the resist layer, errors in a diameter or width of the pattern may be effectively reduced.

After completing the exposure, the exposed resist layer may be subjected to heat treatment. Through this, exposed regions within the resist layer may be sufficiently cured overall. The heat treatment may be performed at a temperature from 80° C. to 120° C.

### Development Process

The resist pattern layer forming step may further comprise a development process of developing the exposed resist layer to form the resist pattern layer (40).

In the development process, the exposed resist layer may be developed using a developer to form the resist pattern layer (40). In the case of the resist layer comprising the negative resist of the present disclosure, an unexposed region in the resist layer may be developed through the developer. The developer is not limited as long as it is commonly applied in the resist field, and may be applied.

In the development process, the resist pattern layer (40) may be formed by spraying the developer onto the resist layer. According to the present disclosure, by controlling a spray pressure of the developer, the shape of the resist pattern layer (40) may be precisely controlled overall.

In the development process, the spray pressure of the developer may be 0.13 MPa or more. The spray pressure may be 0.14 MPa or more. The spray pressure may be 0.3 MPa or less. In this case, regions to be removed by the developer in the resist layer may be sufficiently removed, and the shape of the resist pattern layer (40) may be precisely controlled.

A temperature of the developer may be 20° C. or higher. The temperature may be 25° C. or higher. The temperature may be lower than 30° C. In this case, unexposed regions in the resist layer may be effectively dissolved by the developer.

In the development process, the resist layer may be sprayed with the developer while the base substrate (100) passes through a space in which the developer is sprayed. During spraying of the developer, a moving speed of the base substrate (100) may be 2000 mm/min or less. The moving speed may be 1900 mm/min or less. The moving speed may be 1800 mm/min or less. The moving speed may be 500 mm/min or more.

In this case, during the development process, unexposed regions in the resist layer may be sufficiently dissolved by the developer.

Through the development process, the resist pattern layer (40) may be provided. The resist pattern layer (40) may be disposed in contact with an upper surface of the base substrate (100). Another component may be disposed between the resist pattern layer (40) and the upper surface of the base substrate (100). The resist pattern layer (40) may be disposed in contact with an upper surface of the metal base layer (30). Another component may be disposed between the resist pattern layer (40) and the upper surface of the metal base layer (30).

The resist pattern layer (40) may comprise pattern holes having a diameter of 20 μm or less. The diameter of the pattern holes may be 15 μm or less. The diameter of the pattern holes may be 12 μm or less. The diameter of the pattern holes may be 10 μm or less. The diameter of the pattern holes may be 0.5 μm or more. Through this, the metal mask layer may comprise hole patterns having fine diameters, thereby implementing high-density electrical connections in the insulating layer (20) and the like.

The pattern holes may have a height-to-diameter ratio controlled within a range preset in the present disclosure. When pattern holes having a controlled aspect ratio are formed in the resist pattern layer (40) as described above, a diameter distribution of the pattern holes in the resist pattern layer (40) may be further uniform.

The resist pattern layer (40) may comprise pattern holes having a height-to-diameter ratio of 1.3 or less. The resist pattern layer (40) may comprise pattern holes having a height-to-diameter ratio of 1.2 or less. The resist pattern layer (40) may comprise pattern holes having a height-to-diameter ratio of 1.1 or less. The resist pattern layer (40) may comprise pattern holes having a height-to-diameter ratio of 0.5 or more. In this case, pattern holes having a more uniform diameter distribution may be formed in the resist pattern layer (40).

### Metal Mask Layer Forming Step

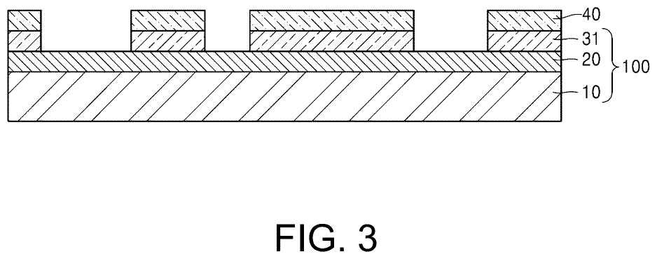

FIG. 3 is a cross-sectional view illustrating a metal mask layer of the present disclosure. The present disclosure will be described with reference to FIG. 3.

What has been described above with reference to FIGS. 1 and 2 may be equally applied to the base substrate (100) and the like. Hereinafter, differences will be mainly described.

The method of manufacturing a packaging substrate according to the present disclosure may further comprise a metal mask layer forming step of selectively wet-etching the metal base layer using the resist pattern layer (40) to provide a metal mask layer (31). In the metal mask layer forming step, the metal mask layer (31) may be formed from the metal base layer using the resist pattern layer (40) as an etching mask. Through this, a pattern of the resist pattern layer (40) may be transferred to the metal mask layer (31).

In the metal mask layer forming step, the metal base layer may be selectively etched using a liquid etchant to form the metal mask layer (31). The liquid etchant is not limited as long as it is commonly used in the wet etching field, and may be applied.

In the metal mask layer forming step, a liquid etchant may be sprayed onto an upper surface side of the base substrate (100) on which the resist pattern layer (40) is formed, thereby selectively etching regions of the metal base layer not covered by the resist pattern layer (40). A processing time of the wet etching process may be adjusted depending on a thickness of the metal base layer.

After completing formation of the metal mask layer (31), the resist pattern layer (40) disposed on the metal mask layer (31) may be stripped and removed.

### Insulating Pattern Layer Forming Step

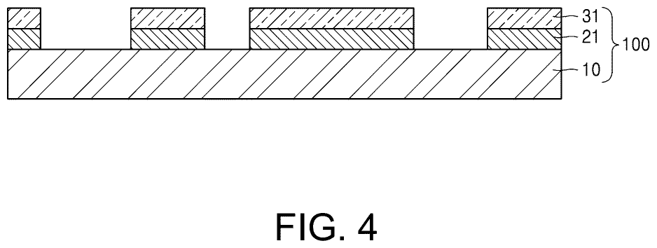

FIG. 4 is a cross-sectional view illustrating an insulating pattern layer of the present disclosure. The present disclosure will be described with reference to FIG. 4.

What has been described above with reference to FIGS. 1 to 3 may be equally applied to the base substrate (100) and the like. Hereinafter, differences will be mainly described.

The method of manufacturing a packaging substrate according to the present disclosure may further comprise an insulating pattern layer forming step of selectively plasma-etching the insulating layer using the metal mask layer (31) to form an insulating pattern layer (21).

In the insulating pattern layer forming step, a pattern of the metal mask layer (31) may be transferred to the insulating layer to form the insulating pattern layer (21).

In the insulating pattern layer forming step, portions of the insulating layer not covered by the metal mask layer (31) may be plasma-etched using the metal mask layer (31) as an etching mask.

The insulating pattern layer forming step may be performed in an atmosphere comprising a first etching gas and a second etching gas. The first etching gas may be a fluorine-based gas. The first etching gas may be any one selected from the group consisting of carbon fluoride, nitrogen fluoride, sulfur fluoride, and combinations thereof. The carbon fluoride may be, for example, any one selected from the group consisting of CF₄, CHF₃, CH₂F₂, CH₃F, and combinations thereof. The nitrogen fluoride may be NF₃. The sulfur fluoride may be SF₆. The first etching gas may be nitrogen fluoride.

The second etching gas may be oxygen gas.

According to the present disclosure, by applying both the first etching gas and the second etching gas as atmospheric gases in the insulating pattern layer forming step, an etching rate for the insulating layer (20) may be further increased.

In the insulating pattern layer forming step, plasma power may be from 1.5 kW to 3 kW. The plasma power may be 1.7 kW or more. The plasma power may be 2 kW or more. The plasma power may be 2.7 kW or less. The plasma power may be 2.5 kW or less. In this case, an etching rate of the insulating layer (20) equal to or higher than a predetermined level may be secured, and excessive damage to the insulating layer (20) due to plasma etching may be prevented.

The insulating pattern layer (21) formed through the insulating pattern layer forming step may comprise pattern holes formed in a thickness direction of the insulating pattern layer (21). The pattern holes may spatially connect an upper surface side and a lower surface side of the insulating pattern layer (21). A conductive layer (not shown) may be disposed in the pattern holes. The conductive layer disposed in the pattern holes may electrically connect a conductive layer (not shown) disposed on the insulating pattern layer (21) and a conductive layer (not shown) disposed under the insulating pattern layer (21).

A diameter of the pattern holes may be 20 μm or less. The diameter may be 15 μm or less. The diameter may be 12 μm or less. The diameter may be 10 μm or less. The diameter may be 0.5 μm or more.

In the insulating pattern layer forming step, after completing formation of the insulating pattern layer (21), the metal mask layer (31) may be removed. The metal mask layer (31) may be removed through wet etching.

### Manufacturing Step

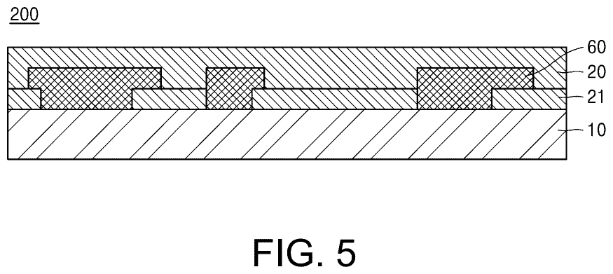

FIG. 5 is a cross-sectional view illustrating a packaging substrate manufactured according to the method of the present disclosure. The method of manufacturing a packaging substrate of the present disclosure will be described with reference to FIG. 5.

What has been described above with reference to FIGS. 1 to 4 may be equally applied to the core layer (10) and the like. Hereinafter, differences will be mainly described.

In the manufacturing step, a packaging substrate (200) may be manufactured from a base substrate on which the patterned insulating layer (21) is formed.

In the manufacturing step, a conductive layer (60) may be formed in regions from which the insulating layer (20) is removed by plasma etching, particularly in the pattern holes. The conductive layer (60) may be formed by a dry method or a wet method.

The dry method is a method in which sputtering is performed on regions in which the conductive layer (60) is to be disposed to form a seed layer, and plating is performed on regions on which the seed layer is formed to form the conductive layer (60). When forming the seed layer, metals such as titanium, chromium, or nickel may be sputtered, and copper may be applied together with the metals during sputtering. Through sputtering, an anchor effect in which a surface on which the conductive layer (60) is disposed interacts with deposited metal particles may occur, thereby improving adhesion of the conductive layer (60).

The wet method is a method in which, after treating regions in which the conductive layer (60) is to be formed with a primer, metal plating is performed. The primer may comprise a compound having a functional group such as an amine group. Depending on a desired degree of adhesion, the primer may comprise a compound having a functional group such as an amine group together with a silane coupling agent. When applying the silane coupling agent, a surface to be treated with the primer may be pretreated with the silane coupling agent, and then a primer layer may be formed by coating a compound having an amine group on the pretreated region.

After forming the seed layer or the primer layer, the conductive layer (60) may be formed by metal plating. When forming the conductive layer (60), copper plating may be applied, but the present disclosure is not limited thereto. Prior to metal plating, regions in which formation of the conductive layer (60) is not required in the seed layer or the primer layer may be deactivated, or regions in which formation of the conductive layer (60) is required may be activated, followed by plating. As a method of activation or deactivation, light irradiation treatment such as irradiation of a laser having a specific wavelength, chemical treatment, or the like may be applied. However, after performing metal plating without applying activation or deactivation treatment, the conductive layer (60) may be etched and patterned according to a pre-designed shape.

Another insulating layer and another conductive layer (not shown) may be formed on the insulating pattern layer (21) and the conductive layer (60). The other insulating layer and the other conductive layer disposed on the insulating pattern layer (21) and the conductive layer (60) may be formed according to the method described above.

The manufacturing step may further comprise forming an insulating pattern layer (not shown) and a conductive layer (not shown) disposed under the core layer (10), as needed. The insulating pattern layer and the conductive layer formed under the core layer (10) may be formed by the same method as described above.

In the manufacturing step, by completing formation of redistribution layers having pre-designed structures on an upper side and/or a lower side of the core layer (10), the packaging substrate (200) may be provided.

As needed, in the manufacturing step, upper terminals and the like may be additionally formed on an upper portion and/or a side portion of the packaging substrate (200), and bumps may be additionally formed on a lower portion of the packaging substrate (200). The bumps may be disposed in a predetermined form under a redistribution layer disposed under the core layer (10). For example, the bumps may be disposed on a portion of a lower surface of the packaging substrate (200) so as to contact a main board or the like. Hereinafter, the present disclosure will be described in more detail through specific examples. The following examples are merely examples for helping understanding of the present disclosure, and the scope of the present disclosure is not limited thereto.

### Manufacturing Example: Manufacturing of Packaging Substrate

Example 1: An insulating layer was formed by vacuum laminating an Ajinomoto Build-up Film (ABF) manufactured by Ajinomoto Co., Inc. on an upper surface of a Corning glass plate SG7.8, thereby providing a base substrate.

A metal base layer was formed on the insulating layer. Specifically, a metal base layer, which was a copper layer having a thickness of 300 nm, was formed by a sputtering process using a copper target on an upper surface of the insulating layer.

A negative resist dry film having a thickness of 7 μm, which was an RY-5107 model manufactured by Showa Denko, was laminated on the metal base layer using a roll laminator, which was a Hot roller manufactured by ATOCHEM. During dry film lamination, a roll temperature of 115° C., a roll pressure of 0.5 MPa, and a laminating speed of 1.5 m/min were applied.

The dry film was exposed in a hole pattern shape having a target diameter of 7 μm using a DLT (Digital Lithography Technology) apparatus manufactured by Applied Materials. During exposure, a wavelength of exposure light was 405 nm, an exposure dose was 210 mJ/cm², and an exposure focus was −3.

After completing exposure, the base substrate was allowed to pass through a region in which a developer was sprayed via a conveyor belt. During spraying of the developer onto the dry film, a spray pressure of the developer was 0.15 MPa, a temperature of the developer was 27° C., and a moving speed of the base substrate during spraying of the developer was 1700 mm/min. After completing spraying of the developer, the dry film was developed to form a resist pattern layer.

The metal base layer was selectively wet-etched using the resist pattern layer to form a metal mask layer. During wet etching, an etchant comprising sodium persulfate in an amount of 10 wt % and water as a solvent was applied.

After forming the metal mask layer, a stripping solution was sprayed onto the composite resist pattern layer, and the composite resist pattern layer was stripped and removed.

The base substrate on which the metal mask layer was formed was placed in an etching chamber, and plasma etching was performed to form hole patterns in the insulating layer. During plasma etching, plasma power was applied in a range from 1.5 kW to 3 kW, and NF₃ at 150 sccm as a first etching gas and O₂ at 150 sccm as a second etching gas were supplied into the chamber.

Thereafter, the metal mask layer was removed using the same etchant as that applied in forming the metal mask layer, thereby manufacturing a packaging substrate.

Example 2: A packaging substrate was manufactured under the same conditions as in Example 1, except that, during exposure of the dry film, an exposure dose of 180 mJ/cm² and an exposure focus of −4 were applied.

Comparative Example 1: A packaging substrate was manufactured under the same conditions as in Example 1, except that a negative resist dry film having a thickness of 10 μm, which was an RY-5110 model manufactured by Showa Denko, was applied as the dry film, an exposure dose of 280 mJ/cm² was applied, a temperature of the developer was 30° C., a spray pressure of the developer was 0.08 MPa, and a moving speed of the base substrate by a conveyor belt during spraying of the developer was applied as 2100 mm/min.

Comparative Example 2: A packaging substrate was manufactured under the same conditions as in Example 1, except that an exposure dose of 165 mJ/cm² and an exposure focus of −5 were applied.

Process conditions for Examples and Comparative Examples are shown in Table 1 below.

### Evaluation Example: Evaluation of Pattern Hole Diameter in Resist Pattern Layer

During manufacturing of the packaging substrates for Examples and Comparative Examples, an average diameter of pattern holes formed in the resist pattern layer was measured and calculated using an optical microscope.

A ratio of the calculated average diameter relative to a target diameter of 7 μm of the pattern holes was calculated.

Measured values for Examples and Comparative Examples are shown in Table 2 below.

TABLE 1

| | | | | | | Base |
|---|---|---|---|---|---|---|
| | | | | | Developer | Substrate |
| | Resist Layer | Exposure | | Developer | Spray | Moving |
| | Thickness | Dose | Exposure | Temperature | Pressure | Speed |
| | (μm) | (mJ/cm²) | Focus | (° C.) | (MPa) | (mm/min) |
| Example 1 | 7 | 210 | −3 | 27 | 0.15 | 1700 |
| Example 2 | 7 | 180 | −4 | 27 | 0.15 | 1700 |
| Comp. Ex. 1 | 10 | 280 | 0 | 30 | 0.08 | 2100 |
| Comp. Ex. 2 | 7 | 165 | −5 | 27 | 0.15 | 1700 |

TABLE 2

| | Ratio of Average |
|---|---|
| | Diameter to |
| | Target Diameter |
| | (%) |
| Example 1 | 100 |
| Example 2 | 100 |
| Comp. Ex. 1 | 40 |
| Comp. Ex. 2 | Greater |
| | than 100 |

As shown in Table 2, with respect to the ratio of the average diameter of the pattern holes relative to the target diameter, Examples 1 and 2 exhibited a value of 100%, whereas Comparative Example 1 exhibited a value of only 40%, and Comparative Example 2 exhibited a value exceeding 100%.

As described above, preferred examples of the present disclosure have been described in detail. However, the scope of the present disclosure is not limited thereto, and various modifications and variations made by those skilled in the art using the basic concept of the present disclosure as defined in the following claims also fall within the scope of the present disclosure.

### DESCRIPTION OF REFERENCE NUMERALS

100: Base substrate
10: Core layer
20: Insulating layer
21: Insulating pattern layer
30: Metal base layer
31: Metal mask layer
40: Resist pattern layer
60: Conductive layer
200: Packaging substrate

1. A method of manufacturing a packaging substrate, comprising:
a resist pattern layer forming step of forming a resist pattern layer on a base substrate comprising a core layer and a metal base layer formed on the core layer,
wherein the resist pattern layer forming step comprises a lamination process of laminating a resist layer on the base substrate and an exposure process of selectively exposing the resist layer,
wherein the resist pattern layer comprises pattern holes having a diameter of 20 μm or less,
wherein the resist layer comprises a negative resist, and
wherein an exposure dose of the exposure process is from 170 mJ/cm² to 215 mJ/cm².

2. The method of claim 1,
wherein the resist pattern layer forming step further comprises a development process of developing the exposed resist layer to form the resist pattern layer,
wherein, in the development process, a developer is sprayed onto the resist layer to form the resist pattern layer, and
wherein a spray pressure of the developer is from 0.13 MPa to 3 MPa.

3. The method of claim 2,
wherein a temperature of the developer is 20° C. or higher and lower than 30° C.

4. The method of claim 1,
wherein, in the lamination process, the resist layer is laminated in contact with the metal base layer using a roll laminator, and
wherein a roll pressure of the roll laminator is from 0.3 MPa to 1 MPa.

5. The method of claim 4,
wherein, in the lamination process, a roll temperature of the roll laminator is from 105° C. to 130° C.

6. The method of claim 4,
wherein, in the lamination process, a laminating speed of the roll laminator is from 1 m/min to 2 m/min.

7. The method of claim 1,
further comprising a metal mask layer forming step of selectively wet-etching the metal base layer using the resist pattern layer to provide a metal mask layer.

8. The method of claim 7,
wherein the base substrate further comprises an insulating layer disposed between the metal mask layer and the core layer, and
further comprising an insulating pattern layer forming step of selectively plasma-etching the insulating layer using the metal mask layer to form an insulating pattern layer.

9. The method of claim 8,
wherein, in the insulating pattern layer forming step, the insulating layer is selectively plasma-etched in an atmosphere comprising a first etching gas and a second etching gas,
wherein the first etching gas is a fluorine-based gas, and
wherein the second etching gas is oxygen gas.
